(19) United States
(12) Patent Application Publication
(10) Pub. No.: US 2026/0038604 A1
(43) Pub. Date: Feb. 5, 2026

(54) SEMICONDUCTOR DEVICES AND METHODS OF OPERATING THEREOF, SYSTEMS, AND COMPUTER READABLE STORAGE MEDIUMS

(71) Applicant: Yangtze Memory Technologies Holding Co., Ltd., Wuhan (CN)

(72) Inventors: Wendong WANG, Wuhan (CN); Feng XU, Wuhan (CN); Xinran LI, Wuhan (CN); Wenhao XIONG, Wuhan (CN); Lei JIN, Wuhan (CN); Zongliang HUO, Wuhan (CN)

(21) Appl. No.: 19/286,112

(22) Filed: Jul. 30, 2025

Related U.S. Application Data
(63) Continuation of application No. PCT/CN2025/082983, filed on Mar. 17, 2025.

(30) Foreign Application Priority Data
Aug. 2, 2024 (CN) 202411061486.X

(51) Int. Cl. G11C 16/26; G11C 16/04; G11C 16/10; G11C 16/30

(52) U.S. Cl. CPC G11C 16/26; G11C 16/0483; G11C 16/102; G11C 16/30

(57) ABSTRACT

Semiconductor devices, methods of operating thereof, systems and computer readable storage mediums are provided. An example semiconductor device includes a memory array and a peripheral circuit coupled to the memory array. The memory array includes a plurality of memory blocks. During an operation phase using the semiconductor device, the peripheral circuit is configured to: apply a first read voltage to a target word line coupled to a target memory block, apply a corresponding input voltage to a plurality of first select lines coupled to the target memory block respectively, apply a first turn-on voltage to a non-target word line coupled to the target memory block, and sense a current on a bit line coupled to the target memory block.

### CROSS-REFERENCE TO RELATED APPLICATIONS

This application is a continuation of International Application No. PCT/CN2025/082983, filed on Mar. 17, 2025, which claims priority to Chinese Patent Application No. 202411061486.X, filed on Aug. 2, 2024. The disclosures of the aforementioned applications are hereby incorporated by reference in their entireties.

### TECHNICAL FIELD

The present disclosure relates to the field of semiconductor technology, and in particular, to a semiconductor device and a method of operating thereof, a system and a computer readable storage medium.

### BACKGROUND

In a classical Von Neumann computing architecture, a memory is separated from a processor, and data is transmitted between the memory and the processor through a data bus. When executing a command, the processor first reads the data from the memory, and then writes the updated data back into the memory after processing is completed, the frequent data migration brings huge power consumption and time overheads. In addition, since the memory bandwidth is limited, the processing speed of the processor is limited by the access speed of the memory, which greatly affects computing performance. With the rise of applications such as big data and artificial intelligence, massive data processing makes the bottleneck of the Von Neumann computing architecture more and more prominent.

### SUMMARY

In view of this, examples of the present disclosure provide a semiconductor device and a method of operating thereof, a system and a computer readable storage medium.

In a first aspect, an example of the present disclosure provides a semiconductor device, the semiconductor device includes a memory array and a peripheral circuit coupled to the memory array, the memory array includes a plurality of memory blocks, wherein during an operation phase using the semiconductor device, the peripheral circuit is configured to: apply a first read voltage to a target word line coupled to a target memory block; apply a corresponding input voltage to a plurality of first select lines coupled to the target memory block respectively; apply a first turn-on voltage to a non-target word line coupled to the target memory block; and sense a current on a bit line coupled to the target memory block.

In an optional implementation, during the operation phase using the semiconductor device, the peripheral circuit is configured to pre-charge a sensing node coupled to the bit line coupled to the target memory block to a target voltage.

In an optional implementation, a memory cell in the target memory block is configured to store one bit of data, a plurality of memory cells in the target memory block have a first memory state and a second memory state, a threshold voltage of the memory cell having the first memory state is less than a threshold voltage of the memory cell having the second memory state, the first read voltage is greater than the threshold voltage of the memory cell having the first memory state, and is less than the threshold voltage of the memory cell having the second memory state.

In an optional implementation, the current on the bit line coupled to the target memory block is a sum of output currents of a plurality of memory cell strings in the target memory block coupled to the bit line; the output current of the memory cell string is greater than or equal to a preset current in a case where the input voltage applied to the first select line coupled to the memory cell string causes a select transistor coupled to the first select line to be in a turn-on state and the memory cell in the memory cell string coupled to the target word line has the first memory state.

In an optional implementation, a memory cell in the target memory block is configured to store m bits of data, a plurality of memory cells in the target memory block are configured to have 2^{m} memory states, the first read voltage is between threshold voltage distributions corresponding to two adjacent memory states, wherein m is an integer greater than 1.

In an optional implementation, during the operation phase using the semiconductor device, the peripheral circuit is configured to apply a second read voltage to the target word line coupled to the target memory block, wherein the second read voltage is between threshold voltage distributions corresponding to two adjacent memory states, and the first read voltage is different from the second read voltage.

In an optional implementation, during the operation phase using the semiconductor device, the peripheral circuit is configured to apply a second turn-on voltage to a plurality of second select lines coupled to the target memory block respectively.

In an optional implementation, the first select line is one of a top select line and a bottom select line, and the second select line is the other of the top select line and the bottom select line.

In an optional implementation, the peripheral circuit is configured to apply a corresponding program voltage to the target word line coupled to the target memory block to program a memory cell coupled to the target word line before performing an operation by using the semiconductor device.

In an optional implementation, at least two of the plurality of memory blocks are target memory blocks, and the peripheral circuit is configured to:
apply the corresponding first read voltage to target word lines individually coupled to the at least two target memory blocks respectively;
apply the corresponding input voltage to a plurality of first select lines individually coupled to the at least two target memory blocks respectively;
apply the first turn-on voltage to non-target word lines individually coupled to the at least two target memory blocks respectively;
Sense currents on bit lines coupled to the at least two target memory blocks.

In an optional implementation, the memory array includes a plurality of memory planes, and the memory plane includes a plurality of memory blocks; and the peripheral circuit is configured to: obtain an operation result corresponding to the memory plane based on the current on the bit line coupled to the target memory block in the memory plane; and perform a logical operation based on operation results corresponding to the plurality of memory planes.

In an optional implementation, the memory plane includes a plurality of memory banks, and the memory bank includes a plurality of memory blocks; and the peripheral circuit is configured to apply the first turn-on voltage to non-target word lines individually coupled to the plurality of memory banks respectively.

In an optional implementation, the peripheral circuit is configured to: sequentially apply the first read voltage to target word lines individually coupled to the plurality of memory banks in a preset order, and sequentially apply the corresponding input voltage to first select lines individually coupled to the plurality of memory banks in a preset order; and sequentially sense currents on bit lines coupled to the memory bank in a preset order.

In an optional implementation, the peripheral circuit is configured to: apply the first read voltage to target word lines individually coupled to a plurality of memory blocks of the memory bank respectively; apply the corresponding input voltage to a plurality of first select lines individually coupled to a plurality of memory blocks of the memory bank respectively; and sense currents on bit lines coupled to a plurality of memory blocks of the memory bank.

In an optional implementation, the peripheral circuit includes an analog-to-digital conversion circuit, a digital-to-analog conversion circuit, a voltage generator, a column decoder, and a control logic; wherein the analog-to-digital conversion circuit is coupled to the column decoder and the control logic; and the digital-to-analog conversion circuit is coupled to the voltage generator and the control logic.

In an optional implementation, the semiconductor device includes a three-dimensional NAND type memory.

In an optional implementation, the semiconductor device includes a first semiconductor structure and a second semiconductor structure; the memory array is located in the first semiconductor structure, the peripheral circuit is located in the second semiconductor structure, and the first semiconductor structure and the second semiconductor structure are stacked along a thickness direction of the semiconductor device.

In a second aspect, an example of the present disclosure provides a system, including: at least one semiconductor device according to any one of the above implementations; a controller coupled to the at least one semiconductor device and configured to send an input data to the semiconductor device and receive an operation result of the semiconductor device.

In a third aspect, an example of the present disclosure provides a method of operating a semiconductor device, during an operation phase using the semiconductor device, the method includes: applying a first read voltage to a target word line coupled to a target memory block; applying a corresponding input voltage to a plurality of first select lines coupled to the target memory block respectively; applying a first turn-on voltage to a non-target word line coupled to the target memory block; and sensing a current on a bit line coupled to the target memory block.

In an optional implementation, during the operation phase using the semiconductor device, the method further includes: pre-charging a sensing node coupled to the bit line coupled to the target memory block to a target voltage.

In an optional implementation, a memory cell in the target memory block is configured to store one bit of data, a plurality of memory cells in the target memory block have a first memory state and a second memory state, a threshold voltage of the memory cell having the first memory state is less than a threshold voltage of the memory cell having the second memory state; the first read voltage is greater than the threshold voltage of the memory cell having the first memory state, and is less than the threshold voltage of the memory cell having the second memory state.

In an optional implementation, the current on the bit line coupled to the target memory block is a sum of output currents of a plurality of memory cell strings in the target memory block coupled to the bit line; the output current of the memory cell string is greater than or equal to a preset current in a case where the input voltage applied to the first select line coupled to the memory cell string causes a select transistor coupled to the first select line to be in a turn-on state and the memory cell in the memory cell string coupled to the target word line has the first memory state.

In an optional implementation, a memory cell in the target memory block is configured to store m bits of data, a plurality of memory cells in the target memory block are configured to have 2^{m} memory states, the first read voltage is between threshold voltage distributions corresponding to two adjacent memory states, wherein m is an integer greater than 1.

In an optional implementation, during the operation phase using the semiconductor device, the method further includes: applying a second read voltage to the target word line coupled to the target memory block, wherein the second read voltage is between threshold voltage distributions corresponding to two adjacent memory states, and the first read voltage is different from the second read voltage.

In an optional implementation, during the operation phase using the semiconductor device, the method further includes: applying a second turn-on voltage to a plurality of second select lines coupled to the target memory block respectively.

In an optional implementation, the first select line is one of a top select line and a bottom select line, and the second select line is the other of the top select line and the bottom select line.

In an optional implementation, the method further includes: applying a corresponding program voltage to the target word line coupled to the target memory block to program a memory cell coupled to the target word line before performing an operation by using the semiconductor device.

In an optional implementation, the memory array includes a plurality of memory planes, and the memory plane includes a plurality of memory blocks; the method further includes: obtaining an operation result corresponding to the memory plane based on the current on the bit line coupled to the target memory block in the memory plane; and performing a logical operation based on operation results corresponding to the plurality of memory planes.

In an optional implementation, the memory plane includes a plurality of memory banks, and the memory bank includes a plurality of memory blocks; and the applying the first turn-on voltage to the non-target word line coupled to the target memory block includes: applying the first turn-on voltage to non-target word lines individually coupled to the plurality of memory banks respectively.

In an optional implementation, the applying the first read voltage to the target word line coupled to the target memory block and applying the corresponding input voltage to the plurality of first select lines coupled to the target memory block respectively include: sequentially applying the first read voltage to target word lines individually coupled to the plurality of memory banks in a preset order, and sequentially applying the corresponding input voltage to first select lines individually coupled to the plurality of memory banks in a preset order; and the sensing the current on the bit line coupled to the target memory block includes: sequentially sensing currents on bit lines coupled to the memory bank in a preset order.

In an optional implementation, the applying the first read voltage to the target word line coupled to the target memory block includes: applying the first read voltage to target word lines individually coupled to a plurality of memory blocks of the memory bank respectively; the applying the corresponding input voltage to the plurality of first select lines coupled to the target memory block respectively includes: applying the corresponding input voltage to a plurality of first select lines individually coupled to a plurality of memory blocks of the memory bank respectively; the sensing the current on the bit line coupled to the target memory block includes: sensing currents on bit lines coupled to a plurality of memory blocks of the memory bank.

In a fourth aspect, an example of the present disclosure provides a computer readable storage medium having a computer program stored thereon, when the computer program is executed by a processor, the method according to any one of the above implementations is performed.

In technical solutions provided by the present disclosure, the peripheral circuit is configured to input a plurality of input voltages corresponding to the input data from the plurality of first select lines coupled to the target memory block into the memory block respectively, apply a read voltage to a target word line coupled to the target memory block, apply a turn-on voltage to a non-target word line coupled to the target memory block, so that multipliers of multiplication operations performed by memory cell strings coupled to different first select lines are different, thereby improving operation flexibility and facilitating more complex operations through the semiconductor device. In addition, the input voltages corresponding to a plurality of elements in the input data can be input simultaneously without being input sequentially, so that operation efficiency can be improved on the basis of improving operation flexibility.

### BRIEF DESCRIPTION OF THE DRAWINGS

FIG. 1 is a schematic structural diagram of a three-dimensional NAND type memory provided by an example of the present disclosure.

FIG. 2 is a schematic diagram of distribution of memory cells of a three-dimensional NAND type memory provided by an example of the present disclosure.

FIG. 3 is a schematic diagram of an example semiconductor device including a peripheral circuit provided by an example of the present disclosure.

FIG. 4 is a schematic cross-sectional view of a memory array including a memory cell string provided by an example of the present disclosure.

FIG. 5 is a first schematic diagram of a semiconductor device including a peripheral circuit and a memory array provided by an example of the present disclosure.

FIG. 6 is a second schematic diagram of a semiconductor device including a peripheral circuit and a memory array provided by an example of the present disclosure.

FIG. 7 is a schematic diagram of inputting an input voltage to a memory block by a word line provided by an example of the present disclosure.

FIG. 8A is a schematic diagram of inputting an input voltage into a memory block by a top select line provided by an example of the present disclosure.

FIG. 8B is a schematic diagram of inputting an input voltage into a memory block by a bottom select line provided by an example of the present disclosure.

FIG. 9 is a schematic diagram of threshold voltage distributions of a memory cell coupled to a target word line provided by an example of the present disclosure.

FIG. 10A is a schematic diagram of a plurality of memory cell strings coupled to one bit line provided by an example of the present disclosure.

FIG. 10B is a first voltage curve of performing an operation by using a semiconductor device provided by an example of the present disclosure.

FIG. 11A is a schematic diagram of a memory bank provided by an example of the present disclosure.

FIG. 11B is a second voltage curve for performing an operation by using a semiconductor device provided by an example of the present disclosure.

FIG. 12 is a schematic diagram of threshold voltage distributions of a memory cell coupled to a target word line provided by another example of the present disclosure.

FIG. 13 is a schematic flowchart of a method of operating a semiconductor device provided by an example of the present disclosure.

FIG. 14A is a first schematic composition diagram of a system provided by an example of the present disclosure.

FIG. 14B is a second schematic composition diagram of a system provided by an example of the present disclosure.

FIG. 15 is a schematic diagram of an example memory card with a memory system provided by an example of the present disclosure.

FIG. 16 is a schematic diagram of an example solid state disk with a memory system provided by an example of the present disclosure.

FIG. 17 is a schematic diagram of a computer readable storage medium provided by an example of the present disclosure.

### DETAILED DESCRIPTION

Exemplary implementations of the present disclosure will be described in more detail below with reference to the drawings. While example implementations of the present disclosure are shown in the drawings, it should be understood that the disclosure may be implemented in various forms and should not be limited by the detailed description set forth herein. Rather, these implementations are provided to enable a more thorough understanding of the present disclosure and to fully convey the scope of the present disclosure to those skilled in the art.

In the following description, numerous specific details are given in order to provide a more thorough understanding of the present disclosure. It will be apparent to those skilled in the art, however, that the present disclosure may be implemented without one or more of these details. In other examples, in order to avoid confusion with the present disclosure, some technical features known in the art are not described; that is, all features of the actual examples are not described herein, and well-known functions and structures are not described in detail.

In the drawings, like reference numerals refer to like elements throughout.

It should be understood that the spatially relative terms, such as “beneath”, “below”, “lower”, “under”, “over”, “upper”, etc, may be used here for ease of description to describe the relationship between one element or feature and other elements or features as illustrated in the figures. It should be understood that the spatially relative terms are intended to further encompass different orientations of a device in use or operation in addition to the orientation depicted in the figures. For example, if the device in the drawings is flipped, then the elements or the features described as “below” or “under” or “beneath” other elements may be oriented “on” the other elements or features. Thus, the example terms “below” and “beneath” may comprise both upper and lower orientations. The device may be orientated otherwise (rotated by 90 degrees or other orientations), and the spatially descriptive words used here are interpreted accordingly.

The terminology used herein is for the purpose of describing particular examples only and is not limiting of the present disclosure. As used herein, the singular forms “a,” “an,” and “the” are intended to comprise a plural form as well, unless otherwise clearly indicated in context. It should also be understood that the terms “consist of” and/or “comprise”, when used in this specification, determine the presence of stated features, integers, operations, operations, elements, and/or components, but do not preclude the presence or addition of one or more other features, integers, operations, operations, elements, components, and/or groups. As used herein, the term “and/or” comprises any and all combinations of related listed items.

In the classical Von Neumann computing architecture, a memory is separate from a processor, and data is transmitted through a data bus between the memory and the processor. When executing a command, the processor first reads the data from the memory, and then writes the updated data back into the memory after processing is completed, the frequent data migration brings huge power consumption and time overheads. In addition, since the memory bandwidth is limited, the processing speed of the processor is limited by the access speed of the memory, which greatly affects the computing performance. With the rise of applications such as big data and artificial intelligence, massive data processing makes the bottleneck of the Von Neumann computing architecture more and more prominent. In order to solve the bottleneck of the classic Von Neumann computing architecture, computation in memory chip architecture emerges, and the basic idea is to embed a computing function in the memory and directly use the memory to perform logic computation, thereby reducing data transmission amount and transmission distance between the memory and the processor, reducing power consumption, and improving computing performance, so that a computing system with high computing power, high bandwidth and high energy efficiency is expected to be constructed.

The computation in memory chip relies on its own physical characteristics while having both storage and computing abilities. The storage ability refers to the ability of different memories to store values by changing their conductance values thereof according to their physical characteristics, and the computing ability refers to the ability to complete vector matrix multiplication computation within a certain time by constructing an array composed of memory devices according to Ohm's law and Kirchhoff's law. The computation in memory chip includes, but is not limited to, static random access memory (SRAM), NAND flash memory, and dynamic random access memory (DRAM). NAND flash memory is a non-volatile memory and has a larger capacity, thus becoming a widely concerned object in a computation in memory chip. The contents of the NAND flash memory will be correspondingly introduced below.

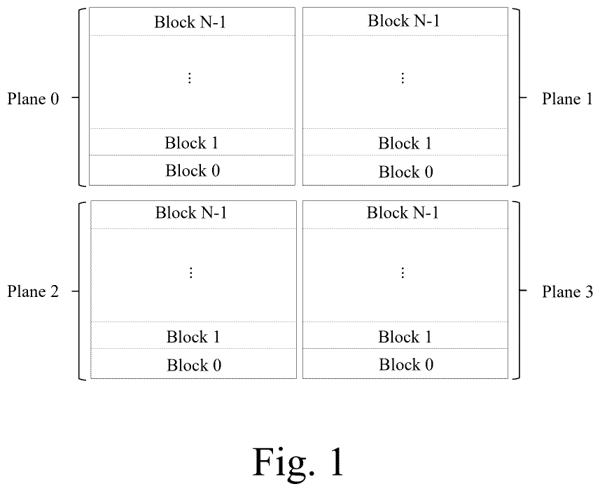

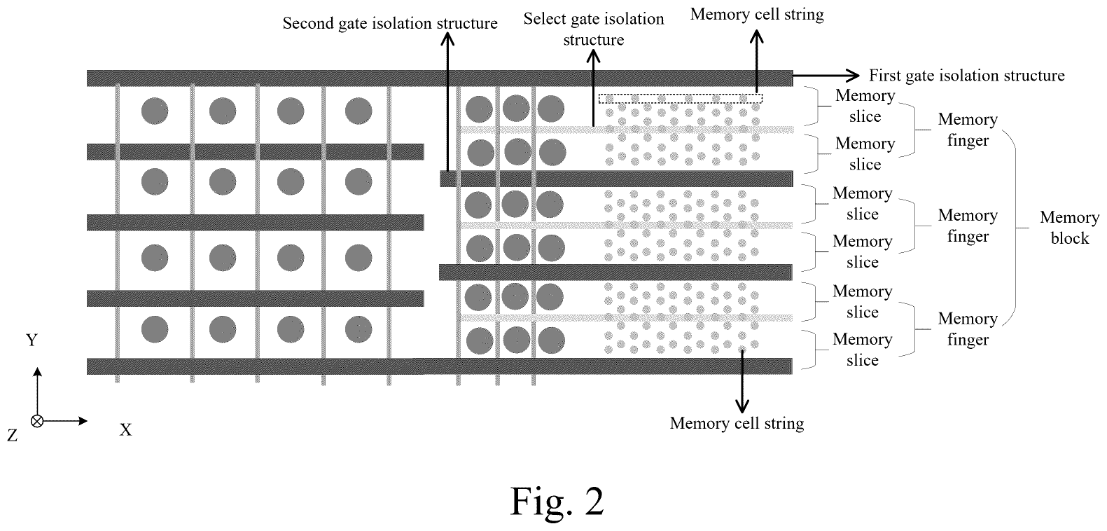

FIG. 1 exemplarily shows a schematic structural diagram of a three-dimensional NAND type memory, and FIG. 2 exemplarily shows a schematic distribution diagram of memory cells of a three-dimensional NAND type memory. The three-dimensional NAND type memory includes a memory array and a peripheral circuit coupled to the memory array. As shown in FIG. 1, the memory array may include a plurality of memory planes, such as Plane 0, Plane 1, Plane 2, and Plane 3, 4 memory planes in total, and each memory plane includes a plurality of memory blocks. As shown in FIG. 2, the memory array of the three-dimensional NAND type memory is composed of a plurality of memory cell rows staggered and parallel to each other and parallel to a gate isolation structure, every four memory cell rows are separated by the gate isolation structure and a select gate isolation structure, each of the memory cell rows includes a plurality of memory cell strings arranged in X direction, one memory cell in each memory cell string is shown in the figure, and the remaining memory cells and this memory cell are stacked along Z direction. Here, the select gate isolation structure may be a top select gate isolation structure that divides a top select gate into a plurality of top select lines. The select gate isolation structure may also be a bottom select gate isolation structure that divides a bottom select gate into a plurality of bottom select lines. The gate isolation structure may include a first gate isolation structure and a second gate isolation structure, the first gate isolation structure divides the memory array into a plurality of memory blocks, the plurality of second gate isolation structures may divide the memory block into a plurality of memory fingers, and the select gate isolation structure disposed in the middle of each memory finger may divide the memory finger into two parts, thereby dividing the memory finger into two memory slices. One memory block shown in FIG. 2 includes 6 memory slices, and in practical applications, the number of memory slices in one memory block is not limited thereto. FIG. 2 exemplarily shows only one memory block of the memory, but the memory includes a plurality of memory blocks as shown in FIG. 2, adjacent memory blocks are separated by the first gate isolation structure, and the plurality of memory blocks may be arranged along the Y direction.

It should be noted that the number of memory cell rows between the gate isolation structure and the select gate isolation structure shown in FIG. 2 is merely an example, and is not intended to limit the number of memory cell rows included in one memory finger of the three-dimensional NAND type memory in the present disclosure. In practical applications, the number of memory cell rows included in one memory finger may be adjusted according to the actual situation, such as 2, 4, 8, 16, etc.

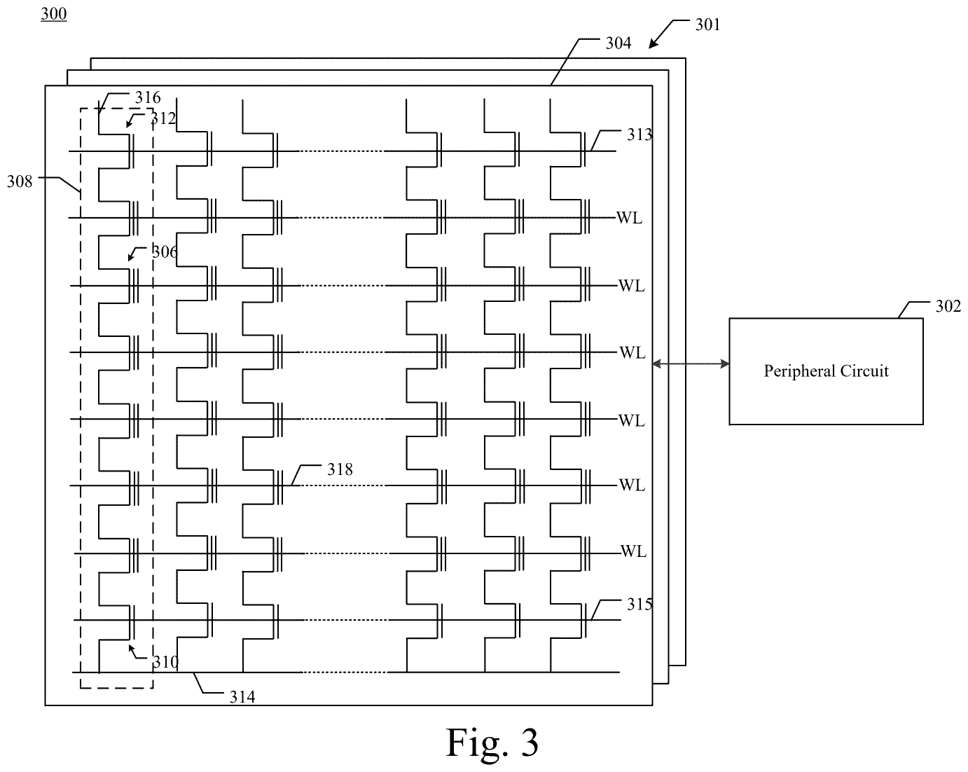

FIG. 3 is a schematic diagram of an example semiconductor device including a peripheral circuit provided by an example of the present disclosure. The semiconductor device 300 may include a memory array 301 and a peripheral circuit 302 coupled to the memory array 301. Taking the memory array 301 as a three-dimensional NAND type memory array as an example for description, a memory cell 306 is a NAND memory cell, the memory cell 306 is provided in the form of an array of memory cell strings 308, and each memory cell string 308 extends vertically. In some implementations, each memory cell string 308 includes a plurality of memory cells 306 coupled in series and stacked vertically. Each memory cell 306 may maintain a continuous analog value, e.g., voltage or charge, depending on the number of electrons captured within the area of the memory cell 306. Each memory cell 306 may be a floating gate type memory cell including a floating gate transistor, or a charge trapping type memory cell including a charge trapping transistor.

In some implementations, each memory cell 306 is a single level cell (SLC) having two possible memory states and thus may store one bit of data. For example, the first memory state “0” may correspond to a first voltage range and the second memory state “1” may correspond to a second voltage range. In some implementations, each memory cell 306 is a multiple level cell capable of storing more than one bit of data in four or more memory states, e.g., a multi-level cell (MLC) storing two bits per cell, a triple level cell (TLC) storing three bits per cell, or a quad-level cell (QLC) storing four bits per cell.

As shown in FIG. 3, each memory cell string 308 may include a bottom select gate (BSG) 310 at its source end and a top select gate (TSG) 312 at its drain terminal. The bottom select gate 310 and the top select gate 312 may be configured to activate the selected memory cell string 308 during read and program operations. In some implementations, the sources of the memory cell strings 308 in the same memory block 304 may be coupled through a common source line (CSL) 314. In other words, all the memory cell strings 308 in the same memory block 304 have an array common source (ACS). According to some implementations, the top select gate 312 of each memory cell string 308 is coupled to a corresponding bit line 316, data may be read from or written to the bit line 316 via an output bus (not shown). In some implementations, each memory cell string 308 is configured to be selected or deselected by applying a select voltage (e.g., a voltage higher than a threshold voltage of the top select gate 312) or a deselect voltage (e.g., OV) to a corresponding top select gate 312 through one or more top select lines (TSL) 313 and/or by applying a select voltage (e.g., a voltage higher than a threshold voltage of the bottom select gate 310) or a deselect voltage (e.g., OV) to a corresponding bottom select gate 310 through one or more Bottom Select Lines (BSL) 315.

As shown in FIG. 3, the memory cell string 308 may be organized into a plurality of memory blocks 304, each of which may have a common source line 314. In some implementations, each memory block 304 is a basic data unit for an erase operation, i.e., all memory cells 306 on the same memory block 304 are erased simultaneously. To erase the memory cells 306 in the selected memory block, a common source line 314 coupled to the selected memory block and an unselected memory block in the same plane as the selected memory block may be biased with an erase voltage. It should be understood that in some examples, the erase operation may be performed at a half memory block level, at a quarter memory block level, or at a level having any suitable number of memory blocks or any suitable fraction of memory block. The memory cells 306 of adjacent memory cell strings 308 may be coupled through a word line 318 that selects which row of memory cells 306 are affected by read and program operations.

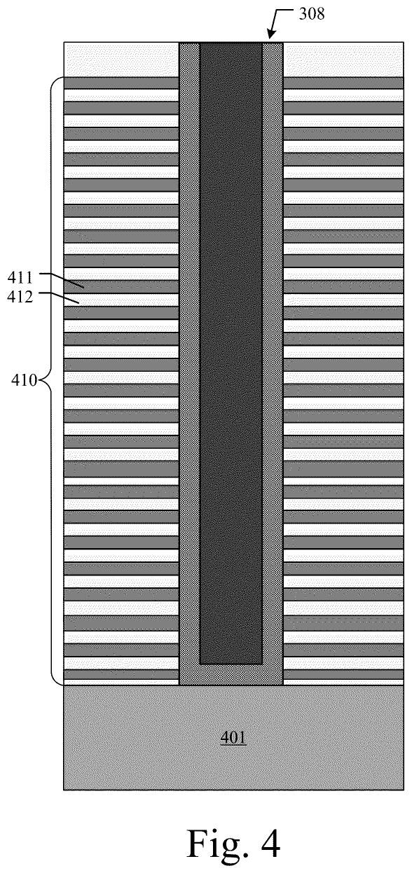

FIG. 4 shows a schematic cross-sectional view of an example memory array including a memory cell string 308, in accordance with some aspects of the present disclosure. As shown in FIG. 4, a stack structure 410 includes a plurality of gate layers 411 and a plurality of insulating layers 412 alternately stacked in sequence, and the memory cell string 308 vertically extending through the gate layers 411 and the insulating layers 412. The gate layers 411 and the insulating layers 412 may be alternately stacked, and two adjacent gate layers 411 are separated by one insulating layer 412. The number of memory cells included in the memory array is mainly related to the number of pairs of gate layers 411 and insulating layers 412 in the stack structure 410.

The constituent material of the gate layer 411 may include a conductive material. The conductive material includes, but is not limited to, tungsten (W), cobalt (Co), copper (Cu), aluminum (Al), polysilicon, doped silicon, silicide, or any combination thereof. In some implementations, each gate layer 411 includes a metal layer, such as a tungsten layer. In some implementations, each gate layer 411 includes a doped polysilicon layer. Each gate layer 411 may include a control gate surrounding the memory cell. The gate layer 411 at the top of the stack structure 410 may extend laterally as a top select line, the gate layer 411 at the bottom of the stack structure 410 may extend laterally as a bottom select line, and the gate layers 411 extending laterally between the top select line and the bottom select line may act as word line layers.

In some examples, the stack structure 410 may be disposed on a semiconductor layer 401. The semiconductor layer 401 may include silicon (e.g., monocrystalline silicon), silicon germanium (SiGe), gallium arsenide (GaAs), germanium (Ge), silicon-on-insulator (SOI), germanium-on-insulator (GOI), or any other suitable material. In other examples, the semiconductor device may not include the semiconductor layer.

In some examples, the memory cell string 308 includes a channel structure that extends vertically through the stack structure 410. In some implementations, the channel structure includes a channel hole filled with semiconductor material(s) (e.g., as a semiconductor channel) and dielectric material(s) (e.g., as a memory film). In some implementations, the semiconductor channel includes silicon, e.g., polysilicon. In some implementations, the memory film is a composite dielectric layer including a tunneling layer, a storage layer (also referred to as a “charge trapping/storage layer”), and a blocking layer. The channel structure may have a cylindrical shape (e.g., a pillar shape). According to some implementations, the semiconductor channel, the tunneling layer, the storage layer, and the blocking layer are arranged radially from a center of the pillar toward an outer surface of the pillar in this order. The tunneling layer may include silicon oxide, silicon oxynitride, or any combination thereof. The storage layer may include silicon nitride, silicon oxynitride, or any combination thereof. The blocking layer may include silicon oxide, silicon oxynitride, high-k dielectric, or any combination thereof. In one example, the memory film may include a composite layer of silicon oxide/silicon oxynitride/silicon oxide (ONO).

Referring back to FIG. 3, the peripheral circuit 302 may be coupled to the memory array 301 through the bit lines 316, the word lines 318, the source lines 314, the BSLs 315, and the TSLs 313. The peripheral circuit 302 may include any suitable analog, digital, and mixed-signal circuit for facilitating operation of the memory array 301 by applying voltage signals and/or current signals to and sensing voltage signals and/or current signals from each target memory cell 306 via the bit lines 316, the word lines 318, the source lines 314, the BSLs 315, and the TSLs 313. The peripheral circuit 302 may include various types of peripheral circuits formed using metal-oxide-semiconductor technology.

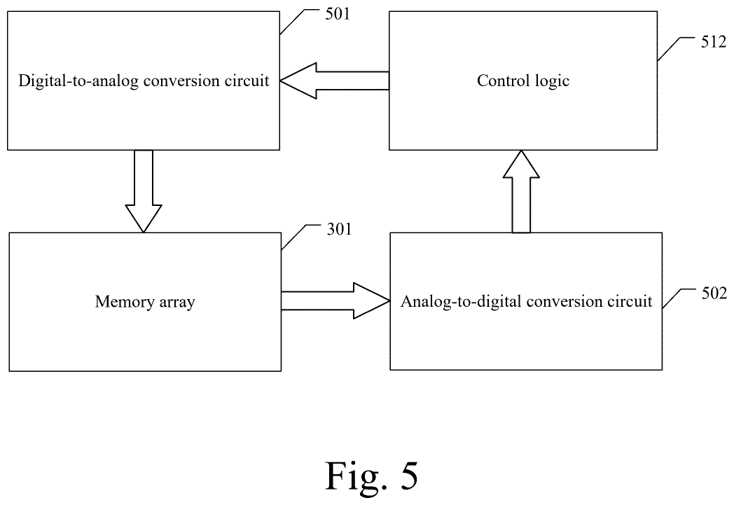

FIG. 5 is a first schematic diagram of a semiconductor device including a peripheral circuit and a memory array provided by an example of the present disclosure. Referring to FIG. 3 and FIG. 5 in combination, the peripheral circuit 302 may include a control logic 512, a digital-to-analog conversion circuit 501 coupled to the control logic 512 and the memory array 301, and an analog-to-digital conversion circuit 502 coupled to the memory array 301 and the control logic 512. During an operation phase using the semiconductor device, the digital-to-analog conversion circuit 501 may convert a digital signal into a voltage signal required by the memory array 301 in the computation in memory chip. The analog-to-digital conversion circuit 502 may convert a current signal output by the memory array 301 into a digital signal. The control logic 512 may be coupled to the peripheral circuit and configured to control operation of the peripheral circuit. The control logic 512 may be further configured to receive an input data sent by a controller, and send the operation result to the controller.

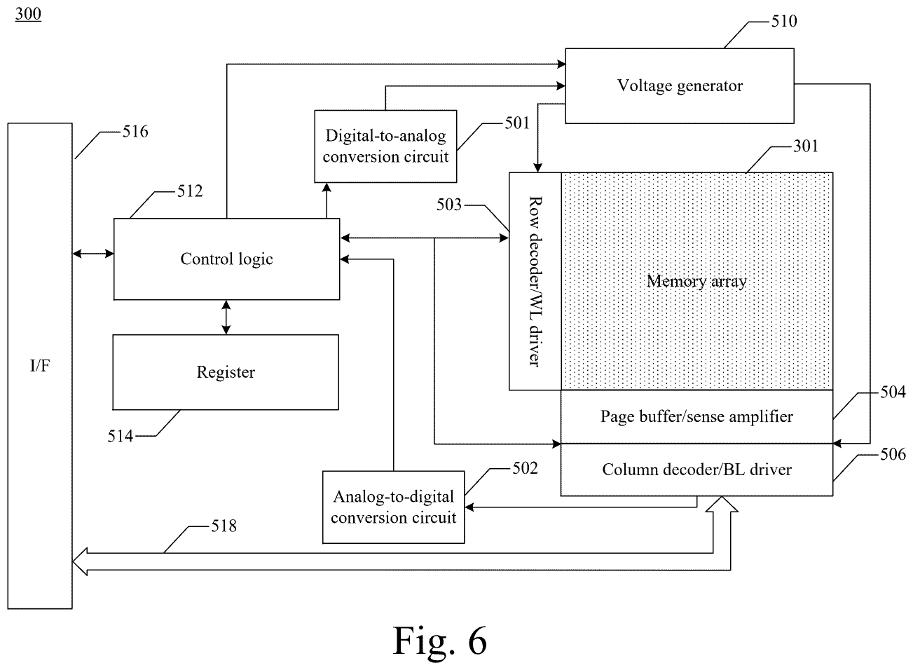

FIG. 6 is a second schematic composition diagram of a semiconductor device provided by an example of the present disclosure, in addition to the circuit structure shown in FIG. 5, the peripheral circuit 302 may further include a page buffer/sense amplifier 504, a column decoder/bit line driver 506, a row decoder/word line driver 508, a voltage generator 510, a register 514, an interface 516, and a data bus 518. It should be understood that in some examples, additional peripheral circuits not shown in FIG. 5 and FIG. 6 may also be included.

The page buffer/sense amplifier 504 may be configured to read data from and program (write) data into the memory array 301 according to control signals from the control logic 512. In one example, the page buffer/sense amplifier 504 may store one page of programming data (write data) to be programmed into one page of the memory array 301. In another example, the page buffer/sense amplifier 504 may perform a program verify operation to ensure that the data has been properly programmed into the memory cell 306 coupled to the selected word line 318. In yet another example, the page buffer/sense amplifier 504 may also sense a low power signal from the bit line 316 representing a data bit stored in the memory cell 306, and amplify small voltage swing to identifiable logic level in a read operation. The column decoder/bit line driver 506 may be configured to be controlled by the control logic 512 and select one or more memory cell strings 308 by applying a bit line voltage generated from the voltage generator 510.

The row decoder/word line driver 508 may be configured to be controlled by the control logic 512 and select/deselect the memory block 304 of the memory array 301 and select/deselect the word line 318 of the memory block 304. The row decoder/word line driver 508 may further be configured to drive the word line 318 using the word line voltage generated from the voltage generator 510. In some implementations, the row decoder/word line driver 508 may further select/deselect and drive the BSL 315 and the TSL 313. As described in detail below, the row decoder/word line driver 508 is configured to perform a programming operation on the memory cells 306 coupled to the selected word line(s) 318. The voltage generator 510 may be configured to be controlled by the control logic 512 and generate a word line voltage (e.g., a read voltage, a program voltage, a pass voltage, a local voltage, a verify voltages, etc., an input voltage), a bit line voltage, and a source line voltage to be supplied to the memory array 301.

The register 514 may be coupled to the control logic 512 and include a status register, a command register, and an address register for storing status information, command operation code (OP code), and command address for controlling operation of each peripheral circuit. The interface 516 may be coupled to the control logic 512 and act as a control buffer to buffer control command received from a host device and relay it to the control logic 512 and buffer status information received from the control logic 512 and relay it to the host device. The interface 516 may further be coupled to the column decoder/bit line driver 506 via the data bus 518 and act as a data I/O interface and a data buffer to buffer data and relay it to the memory array 301 or relay or buffer data from the memory array 301.

In some examples, as shown in FIG. 6, the digital-to-analog conversion circuit 501 may be specifically connected to the control logic 512 and the voltage generator 510, and the analog-to-digital conversion circuit 502 may be specifically connected to the control logic 512 and the column decoder/BL driver 506. During the operation phase using the three-dimensional NAND type memory, the control logic may receive the input data sent by the controller, the digital-to-analog conversion circuit converts the input data to a voltage signal that needs to be applied to the word line or the bit line, a corresponding voltage that needs to be applied to the word line or the bit line is generated by the voltage generator, the row decoder/word line driver is configured to drive the selected word line using the word line voltage generated from the voltage generator, or the column decoder/bit line driver is configured to drive the selected bit line using the bit line voltage generated from the voltage generator. The analog operation result obtained after the operation is transmitted to the analog-to-digital conversion circuit through the page buffer and the column decoder, the analog operation result is converted into a digital operation result through the analog-to-digital conversion circuit, and the final digital operation result is transmitted to the control logic.

In some examples, for the computation in memory chip, a product operation or a product accumulation operation of the input data and a weight matrix needs to be implemented, the input data may be an input vector or an input matrix composed of a plurality of elements, the weight matrix is composed of a plurality of weights, and a product accumulation operation of each element in the input data and the plurality of weights in the weight matrix needs to be performed to obtain a corresponding element in the output data.

To implement the above operation functions, the memory array 301 in the semiconductor device 300 may be configured to store the weight matrix, and specifically, the weights in the weight matrix may be written into the memory array 301 according to a certain mapping rule, and each memory cell 306 in the memory array 301 may be configured to store one weight. During an inference operation phase, the semiconductor device 300 may receive input data from the controller, the input data may be an input vector or an input matrix composed of a plurality of elements, and each element in the input data may be converted into an input voltage by the digital-to-analog conversion circuit 501, and the input voltage is input into the memory array 301 by the bit line 316 or the word line 318.

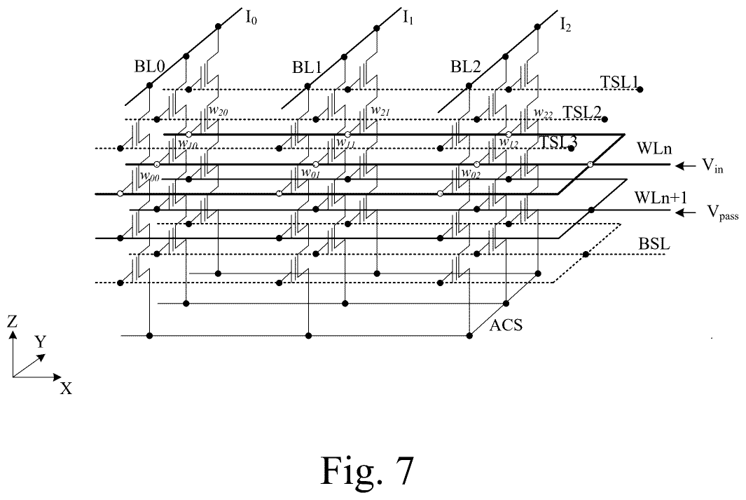

In some examples, FIG. 7 is a schematic diagram of inputting an input voltage into a memory block by a word line. As shown in FIG. 7, the memory cells coupled to a target word line WLn may be configured to store a weight matrix, and specifically, a memory state corresponding to a threshold voltage of the memory cell may correspond to one weight. An input voltage Vᵢₙ may be applied to the target word line WLn, and a turn-on voltage Vpass is applied to a non-target word line coupled to the same memory block, so that the memory cells coupled to the non-target word line are all in a turn-on state. In this case, whether each memory cell string generates a significant current is only related to whether the threshold voltage of the memory cell coupled to the target word line WLn is greater than the input voltage Vᵢₙ. When the input voltage Vᵢₙ is greater than the threshold voltage of the memory cell, the memory cell string to which the memory cell belongs is turned on and generates a significant current; when the input voltage Vᵢₙ is less than the threshold voltage of the memory cell, the memory cell string to which the memory cell belongs is turned off, and no significant current is generated. In this case, the current on the bit line may be detected at an end of each bit line coupled to the sensing circuit, taking the bit line BL0 as an example, the current I₀ thereon corresponds to the result of multiplying the input data corresponding to the input voltage Vᵢₙ by the weights w₀₀, w₁₀, w₂₀ and accumulating the products, the current I₁ on the bit line BL1 corresponds the result of multiplying the input data corresponding to the input voltage Vᵢₙ by the weights w₀₁, w₁₁, w₂₁ respectively and accumulating the products, and the current I₂ on the bit line BL2 corresponds to the result of multiplying the input data corresponding to the input voltage Vᵢₙ by the weights w₀₂, w₁₂, W₂₂ respectively and accumulating the products.

In the above examples, the operation of only one element in the input data and the weight matrix can be performed at a time, the flexibility of the operation is relatively low, and when the input data is an input vector or an input matrix including a plurality of elements, input voltages corresponding to the plurality of elements need to be sequentially input by the target word line WLn, resulting in a long operation period and a low operation efficiency. Therefore, there is a need to further optimize the operation scheme of the semiconductor device including the three-dimensional NAND type memory.

In this regard, the present disclosure provides the following implementations.

The present disclosure provides a semiconductor device, referring back to FIG. 1, FIG. 3 and FIG. 6, the semiconductor device includes a memory array 301 and a peripheral circuit 302 coupled to the memory array 301, the memory array 301 includes a plurality of memory blocks. During an operation phase using the semiconductor device, the peripheral circuit is configured to: apply a first read voltage to a target word line coupled to a target memory block; apply a corresponding input voltage to a plurality of first select lines coupled to the target memory block respectively; apply a first turn-on voltage to a non-target word line coupled to the target memory block; and sense a current on a bit line coupled to the target memory block.

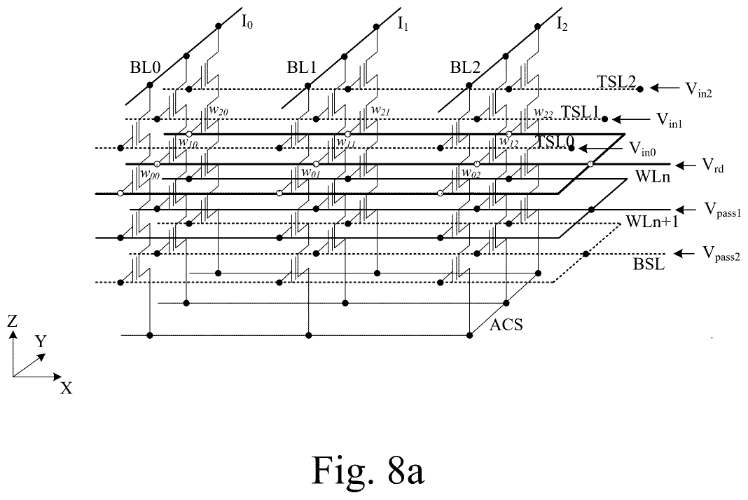

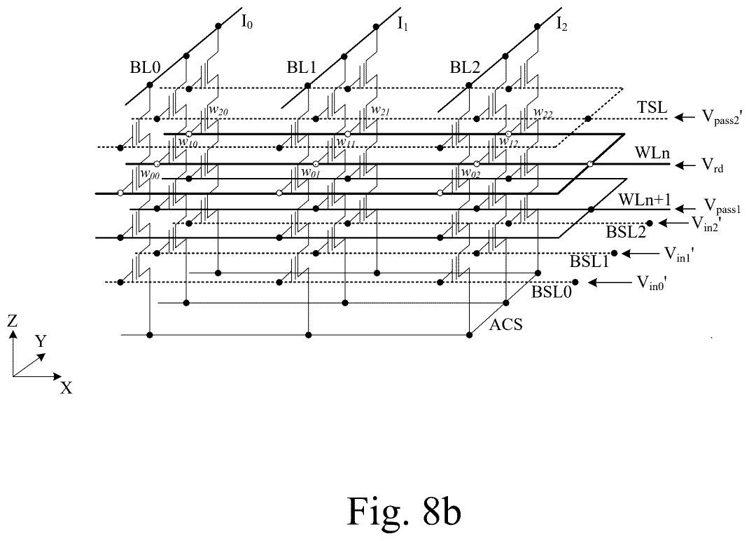

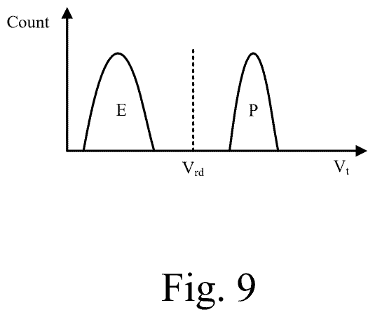

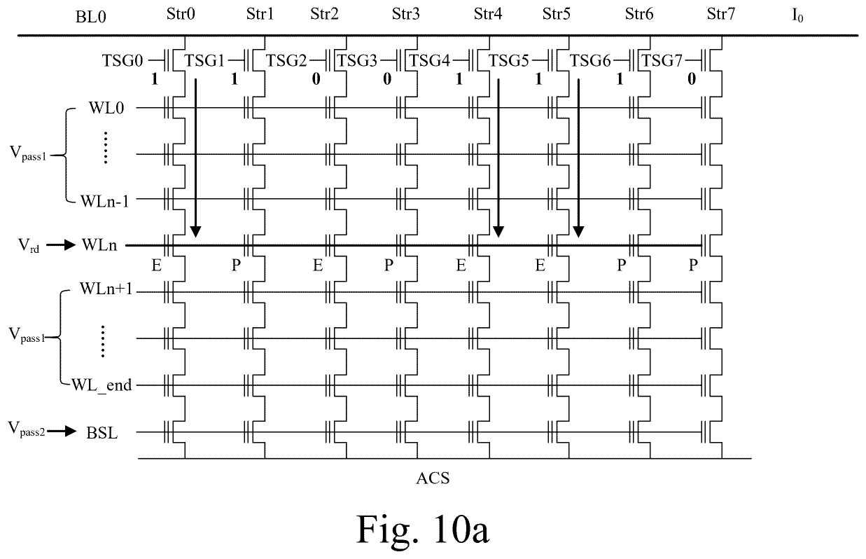

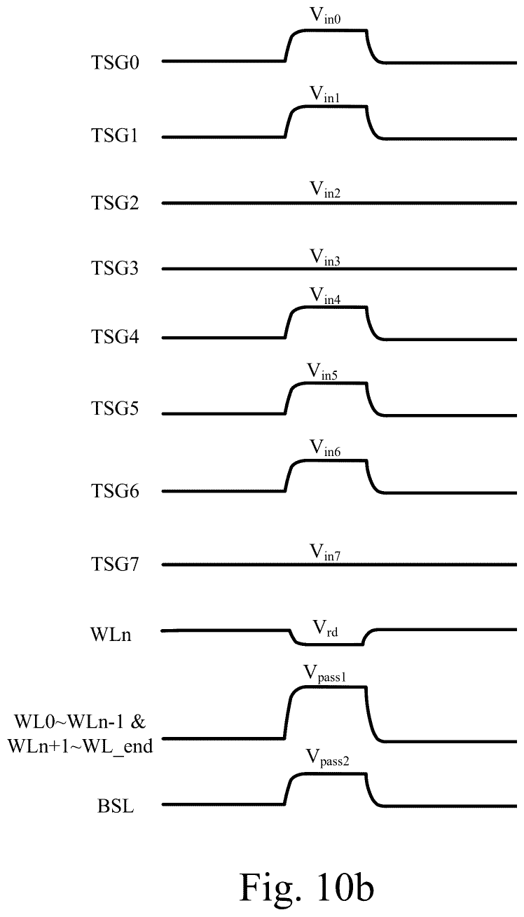

In the examples of the present disclosure, an input voltage corresponding to an element in input data may be input by a first select line, the first select line may be one of a top select line and a bottom select line. FIG. 8A is a schematic diagram of inputting an input voltage into a memory block by a top select line provided by an example of the present disclosure, FIG. 8B is a schematic diagram of inputting an input voltage into a memory block by a bottom select line provided by an example of the present disclosure, FIG. 9 is a schematic diagram of threshold voltage distributions of a memory cell coupled to a target word line provided by an example of the present disclosure, FIG. 10A is a schematic diagram of a plurality of memory cell strings coupled to one bit line provided by an example of the present disclosure, and FIG. 10B is a voltage curve of performing an operation by using a semiconductor device provided by an example of the present disclosure.

It should be noted that the number of the bit lines shown in FIG. 8A, FIG. 8B and FIG. 10A, the number of the memory cell strings coupled to each bit line, and the number of the memory cells in each memory cell string are merely examples, and the present disclosure does not limit the specific number of individual structures.

In some examples, during an operation phase using the semiconductor device, the peripheral circuit is configured to apply a second turn-on voltage to a plurality of second select lines coupled to the target memory block respectively.

In an example of the present disclosure, the first select line is one of a top select line and a bottom select line, and the second select line is the other of the top select line and the bottom select line.

In some specific examples, as shown in FIG. 8A, the first select line is the top select line, the second select line is the bottom select line, and an input voltage corresponding to an element in the input data may be input by a plurality of top select lines. During the operation phase using the semiconductor device, the peripheral circuit is configured to: apply a first read voltage V_{rd} to the target word line WLn coupled to the target memory block, and apply a corresponding input voltage to a plurality of top select lines coupled to the target memory block respectively. For example, the input voltages Vᵢₙ₀, Vᵢₙ₁, Vᵢₙ₂ may be respectively applied to the top select lines TSL0, TSL1, TSL2 coupled to the target memory block, and a first turn-on voltage may be applied to the non-target word line coupled to the target memory block. For example, a first turn-on voltage Vₚₐₛₛ₁ may be applied to a word line WLn+1, and a second turn-on voltage may be applied to the bottom select line coupled to the target memory block. For example, a second turn-on voltage Vₚₐₛₛ₂ may be applied to the bottom select line BSL. The operation result may be obtained by sensing the current on the bit line coupled to the target memory block and converting the current on the bit line. For example, the sum of the product of the element corresponding to the input voltage Vᵢₙ₀ and the weight woo, the product of the element corresponding to the input voltage Vᵢₙ₁ and the weight w₁₀, and the product of the element corresponding to the input voltage Vᵢₙ₂ and the weight w₂₀ may be obtained by sensing the current I₀ on the bit line BL0 and converting the current I₀.

In some specific examples, as shown in FIG. 8B, the first select line is the bottom select line, the second select line is the top select line, and an input voltage corresponding to an element in the input data may be input by a plurality of bottom select lines. During the operation phase using the semiconductor device, the peripheral circuit is configured to: apply a first read voltage V_{rd} to the target word line WLn coupled to the target memory block, and apply a corresponding input voltage to a plurality of bottom select lines coupled to the target memory block respectively. For example, the input voltages Vᵢₙ₀′, Vᵢₙ₁′, Vᵢₙ₂′ may be respectively applied to the bottom select lines BSL0, BSL1, BSL2 coupled to the target memory block, and a first turn-on voltage may be applied to the non-target word line coupled to the target memory block. For example, a first turn-on voltage Vₚₐₛₛ₁′ may be applied to the word line WLn+1, and a second turn-on voltage may be applied to the top select line coupled to the target memory block. For example, a second turn-on voltage Vₚₐₛₛ₂′ may be applied to the top select line TSL. The operation result may be obtained by sensing the current on the bit line coupled to the target memory block and converting the current on the bit line. For example, the sum of the product of the element corresponding to the input voltage Vᵢₙ₀′ and the weight woo, the product of the element corresponding to the input voltage Vᵢₙ₁′ and the weight w₁₀, and the product of the element corresponding to the input voltage Vᵢₙ₂′ and the weight w₂₀ may be obtained by sensing the current I₀ on the bit line BL0 and converting the current I₀.

Hereinafter, the implementation of the operation scheme provided by the examples of the present disclosure will be described by taking the first select line as the top select line, the second select line as the bottom select line, and the input voltage corresponding to the element in the input data being input by the plurality of top select lines as an example.

In some examples, the peripheral circuit is configured to apply a corresponding program voltage to the target word line coupled to the target memory block to program a memory cell coupled to the target word line before performing an operation by using the semiconductor device.

In some specific examples, as shown in FIG. 9, a memory cell in the target memory block is configured to store one bit of data, a plurality of memory cells in the target memory block have a first memory state and a second memory state, a threshold voltage of the memory cell having the first memory state is less than a threshold voltage of the memory cell having the second memory state, the first read voltage V_{rd} is greater than the threshold voltage of the memory cell having the first memory state, and is less than the threshold voltage of the memory cell having the second memory state. Here, the memory cell in the target memory block may be a single level cell SLC storing one bit of data, the first memory state may be an erased state E, and the second memory state may be a programmed state P. The peripheral circuit may be configured to perform a program operation on a memory cell coupled to the target word line before performing the operation, write the weight into the memory cell according to a certain mapping rule. For the single level cell, the process of weight writing includes applying a corresponding program voltage to adjust a threshold voltage of a portion of the memory cells coupled to the target word line to be within a range of a threshold voltage distribution corresponding to the second memory state.

In some examples, during the operation phase using the semiconductor device, the peripheral circuit is configured to pre-charge a sensing node coupled to a bit line coupled to the target memory block to a target voltage. Referring back to FIG. 6, the sensing node coupled to the bit line is located in the page buffer/sense amplifier 504.

In some specific examples, after a transistor between the sensing node and the bit line is turned on, if a memory cell string coupled to the bit line is turned on and generates a current, the voltage of the sensing node may decrease from the target voltage, and the current on the bit line may be obtained based on the voltage change of the sensing node within the fixed time period and the duration of the fixed time period.

In some examples, referring to FIG. 10A and FIG. 10B in combination, taking the target memory block including eight memory cell strings coupled to the bit line BL0 as an example, four of the memory cells coupled to the target word line WLn are in the first memory state (the erased state E), the other four memory cells are in the second memory state (the programmed state P), the input data may be input from the eight top select lines TSL0 to TSL7. Specifically, the input data may be an input vector including eight elements that may include five “1” and three “0”, the digital-to-analog conversion circuit may convert each element of the input vector into a corresponding voltage signal, and convert the voltage signal into an input voltage that needs to be applied to the top select line through the voltage generator, and transfer the input voltage to the top select line through a driver coupled to the top select line. Specifically, eight input voltages may be simultaneously applied to the eight top select lines, respectively. The input voltage corresponding to “1” includes Vᵢₙ₀, Vᵢₙ₁, Vᵢₙ₄, Vᵢₙ₅, and Vᵢₙ₆, so that the top select gates TSG 0, TSG 1, TSG 4, TSG 5 and TSG 6 coupled to the top select lines TSL0, TSL1, TSL4, TSL5, and TSL6, respectively, may be turned on, and the input voltage corresponding to “0” includes Vᵢₙ₂, Vᵢₙ₃, Vᵢₙ₇, so that the top select gates TSG2, TSG 3, and TSG 7 coupled to the top select lines TSL2, TSL3, and TSL7, respectively, may be turned off.

In some examples, referring to FIG. 10A and FIG. 10B in combination, during the operation phase using the semiconductor device, the peripheral circuit is configured to: apply the first turn-on voltage Vₚₐₛₛ₁ to the non-target word line coupled to the target memory block to turn on the memory cell coupled to the non-target word line; and apply the second turn-on voltage Vₚₐₛₛ₂ to the bottom select line BSL coupled to the target memory block to turn on the bottom select gate coupled to the bottom select line BSL. Here, the non-target word line may include WL0˜WLn−1 and WLn+1˜WL_end, WL0 represents the first word line coupled to the memory block, and WL_end represents the last word line coupled to the memory block.

It should be noted that in the examples of the present disclosure, it is taken as an example that each of upper and lower sides of the target word line WLn includes a non-target word line, but the present disclosure is not limited thereto. The target word line WLn may be any word line coupled to a memory cell storing a weight in the target memory block.

In some examples, the magnitudes of the first turn-on voltages applied on different non-target word lines may be different, and the magnitudes of the second turn-on voltages applied on different bottom select lines BSL may also be different. Here, it is taken as an example that only one bottom select line BSL is coupled to a memory cell string, but the present disclosure is not limited thereto. Each memory cell string may further include a plurality of bottom select gates, and the magnitudes of the second turn-on voltages applied to different bottom select lines coupled to the same memory cell string may also be different.

In some specific examples, during the operation phase using the semiconductor device, the peripheral circuit may be further configured to apply a voltage lower than the target voltage on the sensing node to the array common source ACS, so that when the transistor between the sensing node and the bit line is turned on and the memory cell string coupled to the bit line is turned on, the memory cell string may generate a current towards the array common source ACS direction.

In the examples of the present disclosure, during the operation phase using the semiconductor device, the peripheral circuit is configured to sense a current on a bit line coupled to the target memory block, and obtain an operation result according to the current. Specifically, the current on the bit line coupled to the target memory block is the sum of the output currents of the plurality of memory cell strings coupled to the bit line in the target memory block; the output current of the memory cell string is greater than or equal to a preset current in a case where the input voltage applied to the first select line coupled to the memory cell string causes a select transistor coupled to the first select line to be in the turn-on state and the memory cell in the memory cell string coupled to the target word line has the first memory state.

Here, the magnitude of the preset current may be set based on the magnitude of the read voltage V_{rd} applied on the target word line WLn, the magnitude of the target voltage on the sensing node coupled to the bit line, and the threshold voltage of the memory cell in the first memory state. In addition, the output current of the memory cell string is greater than or equal to a preset current and output currents greater than or equal to the preset current generated by the memory cell strings coupled to the same bit line are substantially equal in a case where the input voltage applied to the first select line coupled to the memory cell string causes the select transistor coupled to the first select line to be in the turn-on state and the memory cell in the memory cell string coupled to the target word line has the first memory state; and the memory cell string may also generate a current, but the current generated by the memory cell string should be far less than the preset current in a case where the input voltage causes the select transistor coupled to the first select line to be in the turn-off state and/or the memory cell in the memory cell string coupled to the target word line has the second memory state. Therefore, the operation result may be obtained according to a multiple relationship between the current on the bit line and the output current greater than or equal to the preset current.

In a specific example, referring to FIG. 10A, the current I₀ on the bit line BL0 is the sum of the output currents of the eight memory cell strings coupled to the bit line BL0, wherein the input voltage on the top select line coupled to the memory cell strings Str0, Str4 and Str5 causes the top select gates TSG0, TSG4 and TSG 5 to be in the turn-on state, and the memory cells in the memory cell strings Str0, Str4 and Str5 coupled to the target word line WLn have the first memory state (the erased state E), so the memory cell strings Str0, Str4, and Str5 are turned on, currents greater than or equal to the preset current may be generated, the currents I₀ on the bit line BL0 is substantially equal to the sum of the output currents of the memory cell strings Str0, Str4 and Str5, and the multiple of the current I₀ relative to the current generated by any one of the memory cell strings Str0, Str4 and Str5 is approximately equal to 3. If the weight value stored in the memory cell in the first memory state is equivalent to “1”, and the weight value stored in the memory cell in the second memory state is equivalent to “0”, the operations performed by the eight memory cell strings coupled to the bit line BL0 may be equivalent to: 1*1+1*0+0*1+0*0+1*1+1*1+1*0+0*0=3.

Based on the above specific example, when there are Y+1 memory cell strings coupled to the bit line BLx in the target storage block, the Y+1 elements corresponding to the input voltages input by the Y+1 first select lines are a₀, a₁ . . . , a_{Y}, respectively, and the weights stored in the Y+1 memory cells coupled to the target word line WLn are w₀, w₁, . . . , w_{Y}, respectively, then the operation result equivalent to the multiple of the current on the bit line BLx relative to the output current greater than or equal to the preset current may be a₀*w₀+a₀*w₀+ . . . +a_{Y}*w_{Y}, the multiplication accumulation operation includes Y+1 multiplication operations, and the multipliers a₀, a₁, . . . , a_{Y} in the plurality of multiplication operations are different, and for the entire target memory block, the multipliers of the multiplication operations performed by the memory cell strings coupled to different first select lines may be different, thereby improving operation flexibility and facilitating more complex operations through the semiconductor device. In addition, the input voltages corresponding to the plurality of elements in the input data can be input simultaneously without being input sequentially, so that operation efficiency can be improved on the basis of improving operation flexibility.

In some examples, the semiconductor device may include a plurality of memory blocks, and at least two of the plurality of memory blocks are target memory blocks, and the peripheral circuit may be configured to perform operations with at least two memory blocks simultaneously. Specifically, the peripheral circuit is configured to: apply a corresponding first read voltage to the target word lines individually coupled to the at least two target memory blocks respectively; apply a corresponding input voltage to the plurality of first select lines individually coupled to the at least two target memory blocks respectively; apply the first turn-on voltage to the non-target word lines individually coupled to the at least two target memory blocks respectively; and sense currents on the bit lines coupled to the plurality of target memory blocks.

In some specific examples, the peripheral circuit is configured to: apply the corresponding first read voltage to the target word lines individually coupled to the at least two target memory blocks simultaneously; apply the corresponding input voltage to the plurality of top first select lines individually coupled to the at least two target memory blocks simultaneously; apply the first turn-on voltage to the non-target word lines individually coupled to the at least two target memory blocks simultaneously; and sense the currents on the bit lines coupled to the plurality of target memory blocks simultaneously. Therefore, the plurality of memory blocks in the semiconductor device can perform operations in parallel, so that the computing power of the semiconductor device can be improved.

In some specific examples, the plurality of memory blocks coupled to the same bit line may perform operations simultaneously, and the current on the bit line is the accumulation result after all the memory cell strings coupled to that bit line perform multiplication operations, so that the input data may include more elements.

It should be noted that when performing operations with multiple memory blocks simultaneously, the input data input to different memory blocks may be different, and the first read voltages applied on the target word lines coupled to different memory blocks may also be different.

In some examples, referring back to FIG. 1, the memory array may include a plurality of memory planes, each memory plane includes a plurality of memory blocks, and the peripheral circuit may be configured to perform operations with the plurality of memory planes simultaneously, thereby further improving the computing power of the semiconductor device. Specifically, each of the plurality of memory planes includes a target memory block, and the peripheral circuit may be configured to: obtain an operation result corresponding to the memory plane based on the current on the bit line coupled to the target memory block in the memory plane; and perform a logical operation based on operation results corresponding to the plurality of memory planes, that is, the peripheral circuit may further perform a logical operation again on the operation results output by different memory planes. For example, the peripheral circuit may be configured to add operation results outputted simultaneously by the at least two memory planes.

In some examples, the memory plane may include a plurality of memory banks, and each memory bank includes a plurality of memory blocks; the peripheral circuit may be configured to apply the first turn-on voltage to the non-target word lines individually coupled to the plurality of memory banks respectively.

In some examples, the peripheral circuit may be further configured to: sequentially apply the first read voltage to the target word lines individually coupled to the plurality of memory banks in a preset order, and sequentially apply the corresponding input voltage to the first select lines individually coupled to the plurality of memory banks in a preset order; and sequentially sense the currents on the bit lines coupled to the memory bank in a preset order.

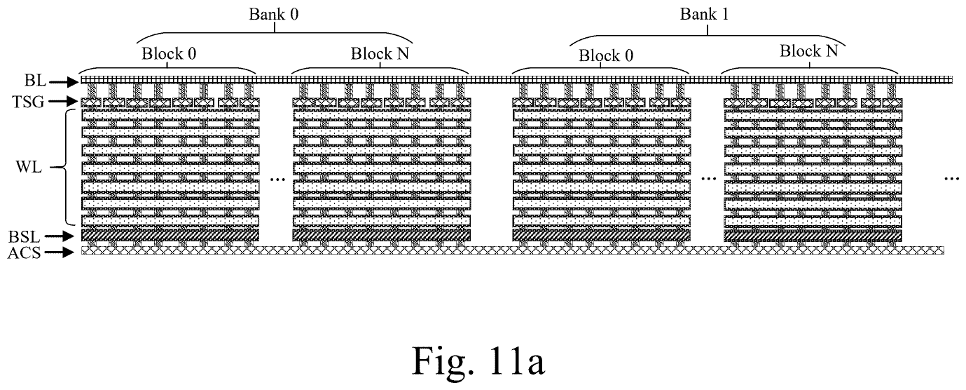

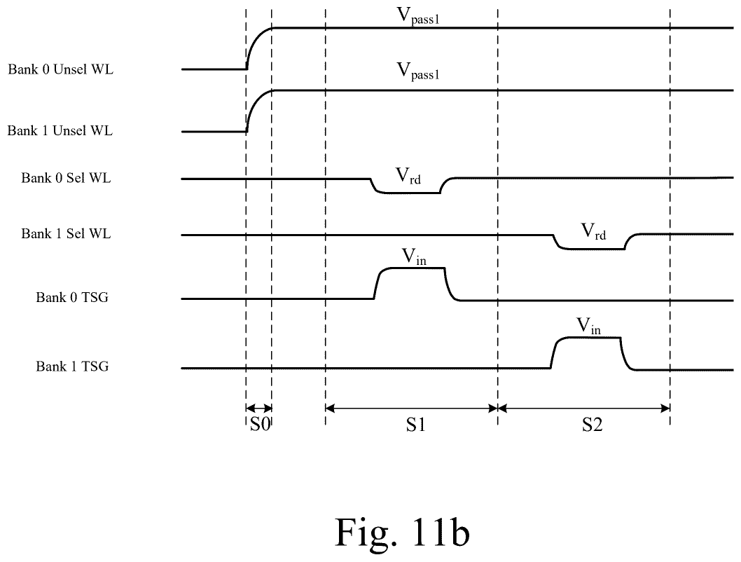

In a specific example, FIG. 11A is a schematic diagram of a plurality of memory banks in a memory plane, and FIG. 11B is a voltage curve of performing an operation by using a plurality of memory banks in a memory plane. Here, for example, the memory plane includes two memory banks Bank 0 and Bank 1, the first select line is a top select line, and the preset order is an order from the memory bank Bank 0 to the memory bank Bank 1.

Referring to FIG. 11A and FIG. 11B in combination, during a phase of performing an operation by using a plurality of memory banks in the memory plane, the peripheral circuit may be configured to apply the first turn-on voltage Vₚₐₛₛ₁ to a non-target word line (Bank 0 Unsel WL) coupled to the memory bank Bank 0 and a non-target word line (Bank 1 Unsel WL) coupled to the memory bank Bank 1 simultaneously, wherein the voltage establishment phase S0 may overlap. During a first operation phase S1, an operation is performed by using the memory bank Bank 0, the first read voltage V_{rd} is applied to a target word line (Bank 0 Sel WL) coupled to the memory bank Bank 0, a corresponding input voltage Vᵢₙ is applied to a first select line (Bank 0 TSG) coupled to the memory bank Bank 0, a current on the bit line BL coupled to the memory bank Bank 0 is sensed, and an operation result of the memory bank Bank 0 may be obtained based on the current on the bit line BL. Then, during a second operation phase S2, an operation is performed by using memory bank Bank 1, the first read voltage V_{rd} is applied to a target word line (Bank 1 Sel WL) coupled to the memory bank Bank 1, the corresponding input voltage Vᵢₙ is applied to a first select line (Bank 1 TSG) coupled to the memory bank Bank 1, a current on the bit line BL coupled to the memory bank Bank 1 is sensed, and an operation result of the memory bank Bank 1 may be obtained based on the current on the bit line BL. Here, the input voltage Vᵢₙ is merely illustrative, and a specific voltage applying manner for the first select line is similar to a manner of applying the corresponding input voltage to the first select line based on the input data in the above examples, and details are not described herein again.

In the examples of the present disclosure, when an operation is needs to be performed by using a plurality of memory banks, the first turn-on voltage may be applied to the non-target word lines in the plurality of memory banks simultaneously, so that voltage establishment phases of the first turn-on voltage applied to the non-select word lines coupled to different memory banks may be overlapped. Compared with a manner of applying the first turn-on voltage to the non-select word lines coupled to different memory banks respectively during different operation phases, overall operation time can be shortened, and operation efficiency of performing an operation by using a plurality of memory banks can be improved.

Further, for each memory bank, an operation may be performed by using the plurality of memory blocks in the memory bank simultaneously, and the peripheral circuit may be configured to: apply the first read voltage to the target word lines individually coupled to the plurality of memory blocks in the memory bank respectively; apply the corresponding input voltage to the plurality of first select lines individually coupled to the plurality of memory blocks in the memory bank respectively; and sense currents on the bit lines coupled to the plurality of memory blocks in the memory bank. Specifically, referring to FIG. 11A and FIG. 11B, taking the first operation phase S1 as an example, the first read voltage V_{rd} may be applied to the target word lines individually coupled to the plurality of memory blocks Block 0 to Block N in the memory bank Bank 0 simultaneously, meanwhile, the corresponding input voltage Vᵢₙ may be applied to the plurality of first select lines individually coupled to the plurality of memory blocks Block 0 to Block N, and the current on the bit line coupled to the plurality of memory blocks Block 0 to Block N may be sensed, and the current on the bit line is the accumulation result after all the memory cell strings coupled to the bit line perform multiplication operations. Therefore, the plurality of memory blocks can perform operations in parallel, so that the operation efficiency and the computing power of the semiconductor device can be further improved.

In the examples of the present disclosure, more complex operations can be implemented without significant variation on the semiconductor device. Specifically, the input of different input data, and the operation of different input data and the weight matrix in the memory array can be implemented only by adjusting the input voltage applied to the first select line, and the adjustment of the input voltage on the first select line can be implemented by the module of the peripheral circuit as shown in FIG. 6 without adding additional circuits, so that the operation performance of the semiconductor device can be improved without occupying more area of the chip.

In the above examples, it is taken as an example that the memory cell in the semiconductor device is a single level cell SLC storing one bit of data. In some other examples, the memory cell in the target memory block is configured to store m bits of data, and the plurality of memory cells in the target memory block are configured to have 2^{m} memory states, wherein m is an integer greater than 1. During the operation phase using the semiconductor device, the first read voltage applied to the target word line may be between threshold voltage distributions corresponding to two adjacent memory states.

In some examples, the peripheral circuit is further configured to: apply a second read voltage to the target word line coupled to the target memory block, wherein the second read voltage is between threshold voltage distributions corresponding to two adjacent memory states, and the first read voltage is different from the second read voltage. Here, each of the first read voltage and the second read voltage may be between two adjacent threshold voltage distributions, or the two threshold voltage distributions closest to the first read voltage are different from the two threshold voltage distributions closest to the second read voltage. Hereinafter, it is taken as an example for description that the two threshold voltage distributions closest to the first read voltage are different from the two threshold voltage distributions closest to the second read voltage.

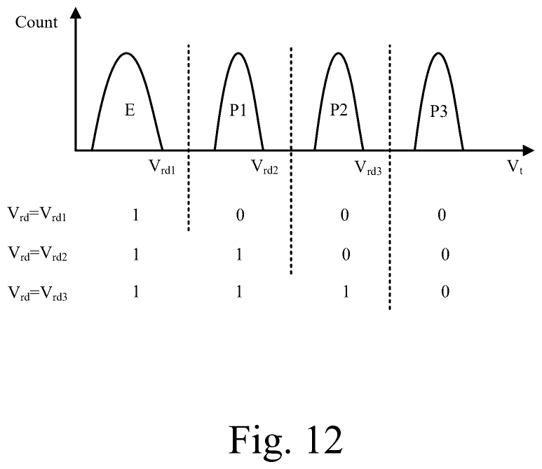

In some specific examples, it is taken as an example that the memory cell is a multi-level cell MLC storing two bits of data, FIG. 12 is a schematic diagram of threshold voltage distributions of a multi-level cell coupled to a target word line provided by an example of the present disclosure. As shown in FIG. 12, when the memory cell is a multi-level cell MLC, the memory cell coupled to the target word line may have four memory states, including an erased state E, a programmed state P1, a programmed state P2, and a programmed state P3, the first read voltage and the second read voltage applied to the target word line may be between threshold voltage distributions corresponding to two adjacent memory states, for example, the first read voltage or the second read voltage may be V_{rd1} between the threshold voltage distribution corresponding to the erased state E and the threshold voltage distribution corresponding to the programmed state P1, or the first read voltage or the second read voltage may be V_{rd2} between the threshold voltage distribution corresponding to the programmed state P1 and the threshold voltage distribution corresponding to the programmed state P2, or the first read voltage or the second read voltage may be V_{rd3} between the threshold voltage distribution corresponding to the programmed state P2 and the threshold voltage distribution corresponding to the programmed state P3, and the first read voltage is different from the second read voltage. In this case, after performing one programming operation on the memory cell to write the weight into the memory cell, the weight stored in the memory cell may be changed only by applying different read voltages to the target word line, for example, when the read voltage is equal to V_{rd1}, the weight stored in the memory cell in the erased state E may be “1”, and the weights stored in the memory cells in the programmed state P1, the programmed state P2, and the programmed state P3 may be “0”, and when the read voltage is equal to V_{rd2}, the weights stored in the memory cells in the programmed state E and the programmed state P1 may be “1”, the weights stored in the memory cells in the programmed state P2 and the programmed state P3 may be “0”, when the read voltage is equal to V_{rd3}, the weights stored in the memory cells in the erased state E, the programmed state P1, and the programmed state P2 may be “1”, and the weight stored in the memory cell in the programmed state P3 may be “0”. Therefore, the first read voltage and the second read voltage may be respectively applied to the target word line to perform an operation on the same input data and different weight matrices to update the weight stored in the memory cell without reprogramming the memory cell, thereby saving the time for updating the weight and further improving the flexibility of the operation function of the semiconductor device.

In some examples, the semiconductor device in the above examples includes a three-dimensional NAND type memory.

In some examples, the semiconductor device in the above examples includes a first semiconductor structure and a second semiconductor structure, the memory array is located in the first semiconductor structure, the peripheral circuit is located in the second semiconductor structure, and the first semiconductor structure and the second semiconductor structure are stacked along a thickness direction of the semiconductor device.

In some examples, the semiconductor device includes a first semiconductor structure, a bonding layer, and a second semiconductor structure stacked along a thickness direction of the semiconductor device; the memory array is located in the first semiconductor structure, the peripheral circuit is located in the second semiconductor structure, and the peripheral circuit is coupled to the memory array through a bonding structure in the bonding layer.

In the examples of the present disclosure, the first semiconductor structure and the second semiconductor structure of the semiconductor device may be formed by bonding two wafers, for example, the first semiconductor structure may be formed on one wafer, the second semiconductor structure may be formed on another wafer, and then the two wafers are bonded, the first semiconductor structure and the second semiconductor structure are stacked along the thickness direction of the semiconductor device. In other examples, the first semiconductor structure and the second semiconductor structure of the semiconductor device may also be formed on the same wafer, but the first semiconductor structure and the second semiconductor structure are stacked along the thickness direction of the semiconductor device, the architecture of the first semiconductor structure and the second semiconductor structure stacked along the thickness direction of the semiconductor device can save the area of the semiconductor device.

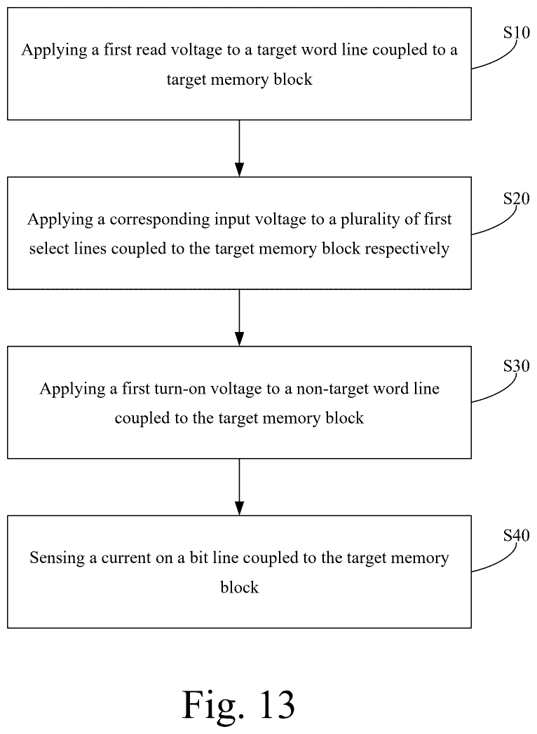

Based on a concept similar to the semiconductor device described above, the present disclosure further provides a method of operating a semiconductor device. FIG. 13 is a schematic flowchart of a method of operating a semiconductor device provided by an example of the present disclosure. As shown in FIG. 13, the method of operating the semiconductor device includes the following operations.

Operation S10: applying a first read voltage to a target word line coupled to a target memory block.

Operation S20: applying a corresponding input voltage to a plurality of first select lines coupled to the target memory block respectively.

Operation S30: applying a first turn-on voltage to a non-target word line coupled to the target memory block.

Operation S40: sensing a current on an output of a bit line coupled to the target memory block.

In some examples, during an operation phase using the semiconductor device, the method further includes: pre-charging a sensing node coupled to the bit line coupled to the target memory block to a target voltage.

In some examples, a memory cell in the target memory block is configured to store one bit of data, a plurality of memory cells in the target memory block have a first memory state and a second memory state, a threshold voltage of the memory cell having the first memory state is less than a threshold voltage of the memory cell having the second memory state; the first read voltage is greater than the threshold voltage of the memory cell having the first memory state and is less than the threshold voltage of the memory cell having the second memory state.

In some examples, the current on the bit line coupled to the target memory block is a sum of output currents of a plurality of memory cell strings in the target memory block coupled to the bit line; the output current of the memory cell string is greater than or equal to a preset current in a case where an input voltage applied to the first select line coupled to the memory cell string causes a select transistor coupled to the first select line to be in a turn-on state, and the memory cell in the memory cell string coupled to the target word line has the first memory state.

In some examples, the memory cell in the target memory block is configured to store m bits of data, the plurality of memory cells in the target memory block are configured to have 2^{m} memory states, the first read voltage is between threshold voltage distributions corresponding to two adjacent memory states, wherein m is an integer greater than 1.

In some examples, during the operation phase using the semiconductor device, the method further includes: applying a second read voltage to the target word line coupled to the target memory block, wherein the second read voltage is between threshold voltage distributions corresponding to two adjacent memory states, and the first read voltage is different from the second read voltage.

In some examples, during the operation phase using the semiconductor device, the method further includes: applying a second turn-on voltage to a plurality of second select lines coupled to the target memory block respectively.

In an example of the present disclosure, the first select line is one of a top select line and a bottom select line, and the second select line is the other of the top select line and the bottom select line.

In some examples, the method further includes: applying a corresponding program voltage to the target word line coupled to the target memory block to program a memory cell coupled to the target word line before performing an operation by using the semiconductor device.

In some examples, the memory array includes a plurality of memory planes, the memory plane includes a plurality of memory blocks, and the method further includes: obtaining an operation result corresponding to the memory plane based on the current on the bit line coupled to the target memory block in the memory plane; and performing a logical operation based on operation results corresponding to the plurality of memory planes.

In some examples, the memory plane includes a plurality of memory banks, and the memory bank includes a plurality of memory blocks; and applying the first turn-on voltage to the non-target word line coupled to the target memory block includes: applying the first turn-on voltage to the non-target word lines individually coupled to the plurality of memory banks respectively.

In some examples, applying the first read voltage to the target word line coupled to the target memory block and applying the corresponding input voltage to the plurality of first select lines coupled to the target memory block respectively include: sequentially applying the first read voltage to the target word lines individually coupled to the plurality of memory banks in a preset order, and sequentially applying the corresponding input voltage to the first select lines individually coupled to the plurality of memory banks in a preset order; and sensing the current on the bit line coupled to the target memory block includes: sequentially sensing currents on bit lines coupled to the memory bank in a preset order.

In some examples, applying the first read voltage to the target word line coupled to the target memory block includes: applying the first read voltage to the target word lines individually coupled to the plurality of memory blocks of the memory bank respectively; applying the corresponding input voltage to the plurality of first select lines coupled to the target memory block respectively includes: applying a corresponding input voltage to a plurality of first select lines individually coupled to a plurality of memory blocks of the memory bank respectively; and sensing the current on the bit line coupled to the target memory block includes: sensing currents on bit lines coupled to a plurality of memory blocks of the memory bank.

In an example of the present disclosure, the method of operating the semiconductor device includes inputting a plurality of input voltages corresponding to input data from the plurality of first select lines coupled to the target memory block into the memory block respectively, and applying a read voltage to the target word line coupled to the target memory block, and applying a turn-on voltage to the non-target word line coupled to the target memory block, so that multipliers used in multiplication operations performed by the memory cell strings coupled to different first select lines may be different, thereby improving flexibility of operations performed by the semiconductor device including the three-dimensional NAND type memory. In addition, the plurality of input voltages corresponding to the input data are input into the memory block simultaneously, and the plurality of memory blocks can perform operations in parallel, and the plurality of memory planes can perform operations in parallel, so that operation efficiency can be improved, and the computing power of the semiconductor device including the three-dimensional NAND type memory can be improved.

Based on a concept similar to the semiconductor device described above, the present disclosure further provides a system, comprising: at least one semiconductor device according to any one of the above examples and a controller coupled to the semiconductor device.

In some examples, the controller is configured to send an input vector or an input matrix to the semiconductor device and to receive an operation result of the semiconductor device. Here, the operation result of the semiconductor device is an operation result after analog-to-digital conversion.

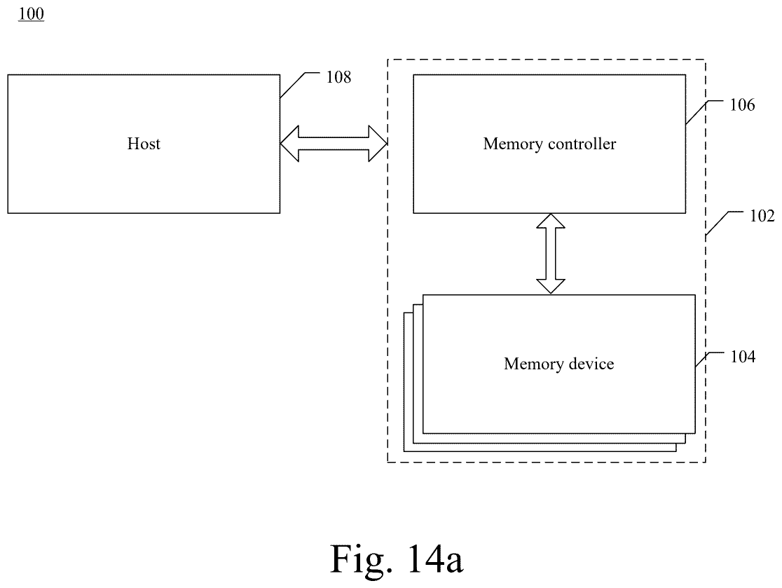

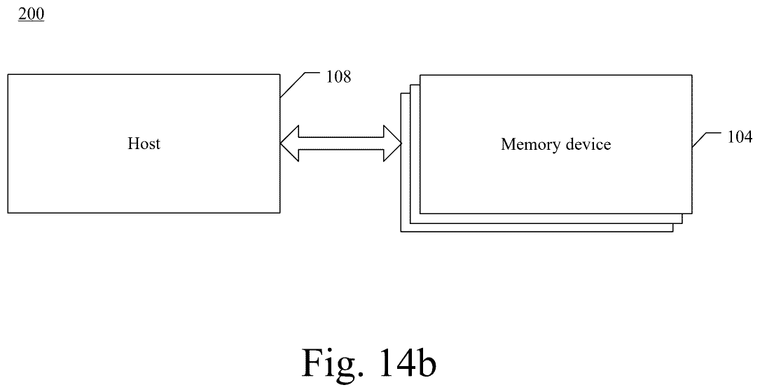

In some examples, the system in the above examples may be a memory system 102 shown in FIG. 14A, the memory system 102 includes a memory controller 106 and a memory device 104 coupled to the memory controller 106, the controller in the above examples may be the memory controller 106, and the semiconductor device may be the memory device 104.

In some other examples, the system in the above examples may be a system 100 shown in FIG. 14A, the system 100 includes a host 108 and a memory system 102 coupled to the host 108, and the controller in the above examples may be a control part independent of the memory controller 106, for example, may be a CPU in a host device.

According to some implementations, as shown in FIG. 14A, the memory controller 106 is coupled to the memory device 104 and the host 108 and is configured to control operations of the memory device 104, such as read, erase, program, compute operations. The memory controller 106 may manage data stored in the memory device 104 and communicate with the host 108.

In some implementations, the system in the above examples may be a system 200 shown in FIG. 14B, the system 200 includes the host 108 and the memory device 104 that can communicate directly with the host 108, the controller in the above examples may be a CPU in the host 108, and the semiconductor device in the above examples may be the memory device 104.

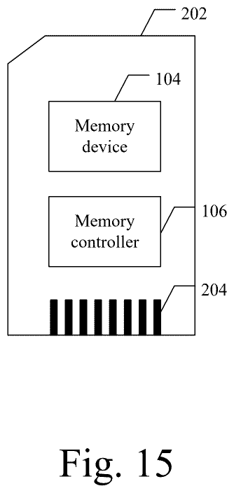

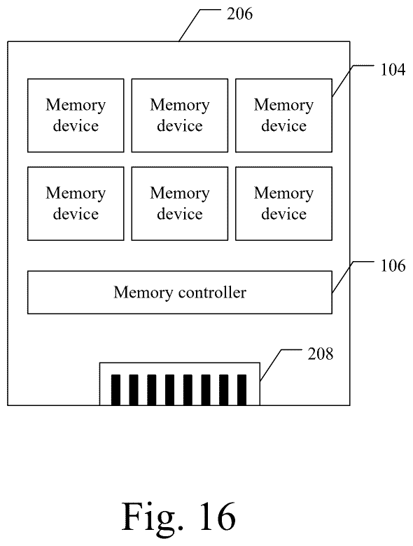

In one example as shown in FIG. 15, the system may be integrated into a memory card 202, the semiconductor device in the system may be the memory 104 in the memory card 202, and the controller in the system may be the memory controller 106 in the memory card 202. The memory card 202 may be one of a compact flash card, a smart media card (SMC), a memory stick (MS), a multi-media card (MMC), such as an RS-MMC, an MMCmicro, an eMMC, etc., a secure digital card, such as a Mini SD card, a Micro SD card, an SDHC card, etc., and a universal flash card. The memory card 202 may further include a memory card connector 204 that couples the memory card 202 to the host. In another example as shown in FIG. 16, the system may be integrated into a solid state disk (SSD) 206, the semiconductor device in the system may be the memory device 104 in the solid state disk 206, and the controller in the system may be the memory controller 106 in the solid state disk 206. The solid state disk 206 may further include a solid state disk connector 208 that couples the solid state disk 206 to the host device. In some implementations, the storage capacity and/or operating speed of the solid state disk 206 is greater than that of the memory card 202.

In some other examples, the system may be integrated into a terminal device, the controller may be a central processing unit (CPU) of the terminal device. Here, the terminal device may include, but is not limited to, any terminal device or portable terminal device such as a mobile phone, a smart television, a smart stereo, a wearable device, a tablet, a desktop computer, an all-in-one computer, a handheld computer, a notebook computer, a server, an ultra-mobile personal computer (UMPC), a netbook, a personal digital assistant (PDA), a laptop, a mobile computer, an augmented reality (AR) device, a virtual reality (VR) device, an artificial intelligence (AI) device, or the like.

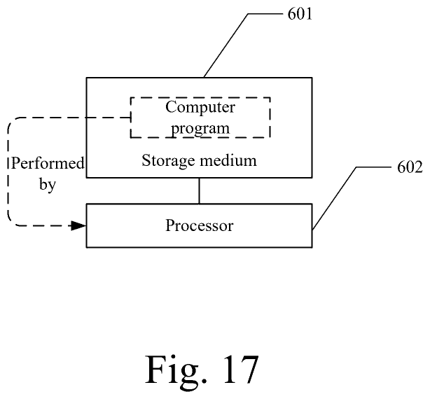

Based on a concept similar to the method of operating the semiconductor device described above, the present disclosure further provides a computer readable storage medium. FIG. 17 is a schematic diagram of a computer readable storage medium provided by an example of the present disclosure. The computer readable storage medium 601 stores a computer program thereon, and when the computer program is executed by the processor 602, the method of operating the semiconductor device in any one of the above examples can be implemented.

In some specific examples, the computer readable storage medium 601 may be a memory such as a ferromagnetic random access memory (FRAM), a read only memory (ROM), a programmable read-only memory (PROM), an erasable programmable read-only memory (EPROM), an electrically erasable programmable read-only memory (EEPROM), a flash memory, a magnetic surface memory, an optical disk, or a compact disc read-only memory (CD-ROM), or the like; or may be various devices including one or any combination of the above memory devices.

The features disclosed in several device examples provided by the present disclosure may be arbitrarily combined without conflict to obtain new device examples.

The methods disclosed in several method examples provided by the present disclosure may be arbitrarily combined without conflict to obtain new method examples.

The above descriptions are only specific implementations of the present disclosure, but the protection scope of the present disclosure is not limited thereto, and any person skilled in the art may easily conceive variations or replacements within the technical scope of the present disclosure, and the variations or replacements should be covered within the protection scope of the present disclosure.

What is claimed is:

1. A semiconductor device, comprising:
a memory array comprising a plurality of memory blocks; and
a peripheral circuit coupled to the memory array, wherein, during an operation phase using the semiconductor device, the peripheral circuit is configured to:
apply a first read voltage to a target word line coupled to a target memory block;
apply a corresponding input voltage to a plurality of first select lines coupled to the target memory block respectively;
apply a first turn-on voltage to a non-target word line coupled to the target memory block; and
sense a current on a bit line coupled to the target memory block.

2. The semiconductor device according to claim 1, wherein, during the operation phase using the semiconductor device, the peripheral circuit is configured to:
pre-charge a sensing node coupled to the bit line coupled to the target memory block to a target voltage.

3. The semiconductor device according to claim 1, wherein a memory cell in the target memory block is configured to store one bit of data, and a plurality of memory cells in the target memory block have a first memory state and a second memory state,
wherein a threshold voltage of the memory cell having the first memory state is less than a threshold voltage of the memory cell having the second memory state, and
wherein the first read voltage is greater than the threshold voltage of the memory cell having the first memory state and is less than the threshold voltage of the memory cell having the second memory state.

4. The semiconductor device according to claim 3, wherein the current on the bit line coupled to the target memory block is a sum of output currents of a plurality of memory cell strings in the target memory block coupled to the bit line,
wherein an output current of a memory cell string is greater than or equal to a preset current in a case where the corresponding input voltage applied to a corresponding first select line coupled to the memory cell string causes a select transistor coupled to the first select line to be in a turn-on state and a memory cell in the memory cell string coupled to the target word line has the first memory state.

5. The semiconductor device according to claim 1, wherein a memory cell in the target memory block is configured to store m bits of data, a plurality of memory cells in the target memory block are configured to have 2^{m} memory states, and the first read voltage is between threshold voltage distributions corresponding to two adjacent memory states, wherein m is an integer greater than 1.

6. The semiconductor device according to claim 5, wherein, during the operation phase using the semiconductor device, the peripheral circuit is configured to:
apply a second read voltage to the target word line coupled to the target memory block, wherein the second read voltage is between the threshold voltage distributions corresponding to the two adjacent memory states, and the first read voltage is different from the second read voltage.

7. The semiconductor device according to claim 1, wherein, during the operation phase using the semiconductor device, the peripheral circuit is configured to:
apply a second turn-on voltage to a plurality of second select lines coupled to the target memory block respectively.

8. The semiconductor device according to claim 7, wherein the first select line is one of a top select line and a bottom select line, and the second select line is the other of the top select line and the bottom select line.

9. The semiconductor device according to claim 1, wherein the peripheral circuit is configured to:
apply a corresponding program voltage to the target word line coupled to the target memory block to program a memory cell coupled to the target word line before performing an operation by using the semiconductor device.

10. The semiconductor device according to claim 1, wherein at least two of the plurality of memory blocks are target memory blocks, and the peripheral circuit is configured to:
apply the corresponding first read voltage to target word lines individually coupled to the at least two target memory blocks respectively;
apply the corresponding input voltage to a plurality of first select lines individually coupled to the at least two target memory blocks respectively;
apply the first turn-on voltage to non-target word lines individually coupled to the at least two target memory blocks respectively; and
sense currents on bit lines coupled to the at least two target memory blocks.

11. The semiconductor device according to claim 1, wherein the memory array comprises a plurality of memory planes, and a memory plane of the plurality of memory planes comprises a plurality of memory blocks, and
wherein the peripheral circuit is configured to:
obtain an operation result corresponding to the memory plane based on a current on a corresponding bit line coupled to a corresponding target memory block in the memory plane; and
perform a logical operation based on operation results corresponding to the plurality of memory planes.

12. The semiconductor device according to claim 11, wherein the memory plane comprises a plurality of memory banks, and a memory bank of the plurality of memory banks comprises a plurality of memory blocks, and
wherein the peripheral circuit is configured to:
apply the first turn-on voltage to non-target word lines individually coupled to the plurality of memory banks respectively.

13. The semiconductor device according to claim 12, wherein the peripheral circuit is configured to:
sequentially apply the first read voltage to target word lines individually coupled to the plurality of memory banks in a first preset order, and sequentially apply the corresponding input voltage to first select lines individually coupled to the plurality of memory banks in a second preset order; and
sequentially sense currents on bit lines coupled to the memory bank in a third preset order.

14. The semiconductor device according to claim 13, wherein the peripheral circuit is configured to:
apply the first read voltage to target word lines individually coupled to the plurality of memory blocks of the memory bank respectively;
apply the corresponding input voltage to a plurality of first select lines individually coupled to the plurality of memory blocks of the memory bank respectively; and
sense currents on bit lines coupled to the plurality of memory blocks of the memory bank.

15. A system, comprising:
at least one semiconductor device each comprising:
a memory array comprising a plurality of memory blocks; and
a peripheral circuit coupled to the memory array, wherein, during an operation phase using the semiconductor device, the peripheral circuit is configured to:
apply a first read voltage to a target word line coupled to a target memory block;
apply a corresponding input voltage to a plurality of first select lines coupled to the target memory block respectively;
apply a first turn-on voltage to a non-target word line coupled to the target memory block; and
sense a current on a bit line coupled to the target memory block; and
a controller coupled to the at least one semiconductor device and configured to send input data to the semiconductor device and receive an operation result of the semiconductor device.

16. A method of operating a semiconductor device, wherein, during an operation phase using the semiconductor device, the method comprises:
applying a first read voltage to a target word line coupled to a target memory block;
applying a corresponding input voltage to a plurality of first select lines coupled to the target memory block respectively;
applying a first turn-on voltage to a non-target word line coupled to the target memory block; and
sensing a current on a bit line coupled to the target memory block.

17. The method according to claim 16, wherein, during the operation phase using the semiconductor device, the method further comprises:
pre-charging a sensing node coupled to the bit line coupled to the target memory block to a target voltage.

18. The method according to claim 16, wherein a memory cell in the target memory block is configured to store a bit of data, a plurality of memory cells in the target memory block have a first memory state and a second memory state, and a threshold voltage of the memory cell having the first memory state is less than a threshold voltage of the memory cell having the second memory state, and
wherein the first read voltage is greater than the threshold voltage of the memory cell having the first memory state, and is less than the threshold voltage of the memory cell having the second memory state.

19. The method according to claim 18, wherein the current on the bit line coupled to the target memory block is a sum of output currents of a plurality of memory cell strings in the target memory block coupled to the bit line, and
wherein the output current of the memory cell string is greater than or equal to a preset current in a case the input voltage applied to the first select line coupled to the memory cell string causes a select transistor coupled to the first select line to be in a turn-on state and the memory cell in the memory cell string coupled to the target word line has the first memory state.

20. The method according to claim 16, wherein a memory cell in the target memory block is configured to store m bits data, a plurality of memory cells in the target memory block are configured to have 2^{m} memory states, the first read voltage is located between threshold voltage distributions corresponding to two adjacent memory states, and m is an integer greater than 1.
